(19) United States
(12) Patent Application Publication
(10) Pub. No.: US 2004/0036120 A1
(43) Pub. Date: Feb. 26, 2004

(54) Semiconductor device

(75) Inventor: Masahiro Shiina, Ora-gun (JP)

Correspondence Address: MORRISON & FOERSTER LLP, 1650 TYSONS BOULEVARD, SUITE 300, MCLEAN, VA, 22102, US

(73) Assignee: Sanyo Electric Co., Ltd., Moriguchi-City (JP)

(21) Appl. No.: 10/606,126

(22) Filed: Jun. 26, 2003

(30) Foreign Application Priority Data
Jun. 28, 2002 (JP) 2002-189620
Aug. 8, 2002 (JP) 2002-231203

(51) Int. Cl. H01L 23/62

(52) U.S. Cl. 257/360

(57) ABSTRACT

Influence of signal noise among circuits formed on a semiconductor device is suppressed. When the noise occurs in a circuit block in the semiconductor device of a stacked configuration having a plurality of circuit blocks, the influence of signal noise on the other circuit blocks is suppressed by forming a box mostly made of metal over the circuit block which generates the noises.

### BACKGROUND OF THE INVENTION

1. Field of the Invention:

This invention relates to a semiconductor device, specifically to a semiconductor device in which influence of a circuit on other circuits is suppressed.

1. Description of the Related Art:

A semiconductor device has a possibility of destruction when an excessive external voltage is applied to its input pin. Various kinds of input protection circuits are incorporated in semiconductor devices to prevent the destruction.

For example, a polysilicon gate MOS integrated circuit is provided with a protection circuit 80, as shown in FIG. 15. The protection circuit 80 includes two diodes D3 and D4 connected in series. A cathode of the protection diode D3 is connected to Vcc (power supply voltage), while an anode of the protection diode D4 is connected to GND (ground voltage). An input terminal 81 is connected to a connecting node 83 between the two protection diodes D3 and D4 and further connected to an internal circuit through a terminal 82.

An excessive external voltage due to an electro static discharge or the like is applied to the input terminal 81 of the protection circuit 80. When a voltage higher than Vcc is applied, the protection diode D3 conducts to clamp the voltage at the connecting node 83, and keeps the internal circuit beyond the terminal 82 from the high voltage. Similarly, when a negative high voltage lower than GND is applied, the protection diode D4 conducts to clamp the voltage at the connecting node 83, and keeps the internal circuit beyond the terminal 82 from the negative high voltage.

FIG. 16 is a plan view of a conventional semiconductor device, that is, an LSI 100 which includes the protection circuit 80. The LSI 100 including three circuit blocks 101A-101C, 16 pads 102A-102P and 16 protection circuits 104A-104P is shown as an example in the figure. The circuit block denotes a circuit containing a plurality of elements such as resistances, transistors, capacitances.

Each of the pads 102A-102P is connected with each of the circuit blocks 101A-101C through an interconnection 103. Each of the protection circuits 104A-104P is connected with each of the pads 102A-102P through an interconnection 105, respectively.

Each of the protection circuits 104A-104P contains a protection circuit 80 shown in FIG. 15 and requires two interconnections (not shown) to electrically connect with a Vcc wiring and a GND wiring formed in the LSI 100. The area each of the protection circuits 104A-104P takes up is about ⅓to ½of that of each of the pads 102A-102P.

In layout design of the semiconductor device shown in FIG. 16, placement of the elements is usually determined through a following procedure.

First, three circuit blocks 101A-101C are placed around a center of the LSI 100. Relationship among positions of the three circuit blocks is determined considering die size and functionality. In FIG. 16, the circuit blocks 101A and 101B having the same area are placed parallel to the largest circuit block 101C.

Second, the pads 102A-102P are placed at regular intervals around the three circuit blocks 101A-101C.

Third, the protection circuits 104A-104P are disposed in the LSI 100. Since each of the protection circuits 104A-104P takes up small area compared with each of the pads 102A-102P, each of the protection circuits 104A-104P is placed in an empty space, or so-called dead space, between the circuit blocks 101A-101C and the pads 102A-102P.

Then, interconnections 103 to electrically connect between the circuit blocks 101A-101C and the pads 102A-102P, and interconnections 105 to electrically connect between the pads 102A-102P and the protection circuits 104A-104P are disposed. In addition, Vcc wiring and GND wiring for the protection circuits 104A-104P are placed.

Among the plurality of circuit blocks formed on the same substrate, some process a high frequency signal while the other need to avoid influence of the high frequency signal (noise, for example). And they are often placed close to each other for reasons of design.

Therefore, adverse effect by the circuit block which processes high frequency on the neighboring circuit block has to be minimized.

This invention is directed to keeping a circuit block from having adverse effects on the neighboring circuit blocks. The invention is also directed to reducing impedance of wiring.

### SUMMARY OF THE INVENTION

The invention provides a semiconductor device that includes a circuit block formed on a semiconductor substrate, and a shield having a lower metal layer, an upper metal layer and an interlayer insulation film disposed between the lower metal layer and the upper metal layer. The shield covers the circuit block. The device may also includes an intermediate metal layer disposed inside the shield.

The invention also provides a semiconductor device that includes a first circuit block formed on a semiconductor substrate, a second circuit block formed on the semiconductor substrate, and a shield having a top portion made of a metal and covering only the first circuit block. The top portion is configured to be at a ground potential.

### BRIEF DESCRIPTION OF DRAWINGS

FIG. 1 is an oblique perspective figure showing a semiconductor device according to a first embodiment of this invention.

FIG. 2 is an oblique perspective figure showing the BOX in FIG. 1.

FIG. 3 is a cross-sectional view showing section X1-X1 in FIG. 2.

FIG. 4 is a cross-sectional view showing section Y1-Y1 in FIG. 2.

FIG. 5 is an oblique perspective figure showing a semiconductor device according to a second embodiment of this invention.

FIG. 6 is an oblique perspective figure showing a semiconductor device according to a third embodiment of this invention.

FIG. 7 is an oblique perspective figure showing the BOX1 in FIG. 5 and FIG. 6.

FIG. 8 is a cross-sectional view showing section X2-X2 in FIG. 7.

FIG. 9 is a cross-sectional view showing section Y2-Y2 in FIG. 7.

FIG. 10 is an oblique perspective figure showing the BOX2 in FIG. 6.

FIG. 11 is a cross-sectional view showing section X3-X3 in FIG. 10.

FIG. 12 is a cross-sectional view showing section Y3-Y3 in FIG. 10.

FIG. 13 is an oblique perspective figure showing the inside of the BOX2 in FIG. 10.

FIG. 14A and FIG. 14B are plan views showing the shielding structures of the BOX according to the first and a fourth embodiments.

FIG. 15 is a circuit diagram showing a protection circuit according to a conventional art.

FIG. 16 is a plan view showing a semiconductor device according to the conventional art.

### DETAILED DESCRIPTION OF THE INVENTION

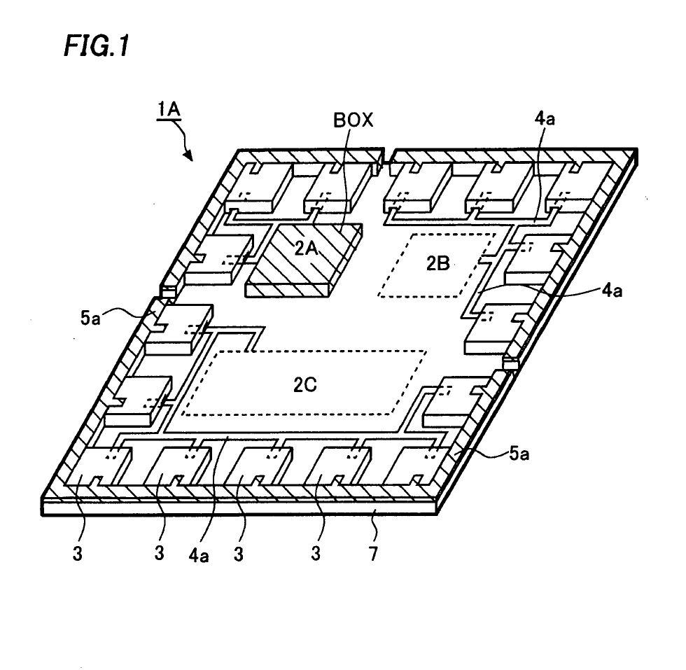

The first embodiment of this invention will be explained referring to FIG. 1 through FIG. 4.

FIG. 1 is an oblique perspective figure showing a semiconductor device 1A according to the first embodiment of this invention.

Structure of the semiconductor device 1A will be explained hereafter. Circuit blocks 2A, 2B and 2C are formed on a semiconductor substrate 12a. Each of the circuit blocks 2A, 2B and 2C includes a plurality of circuit elements such as resistors, transistors and capacitors.

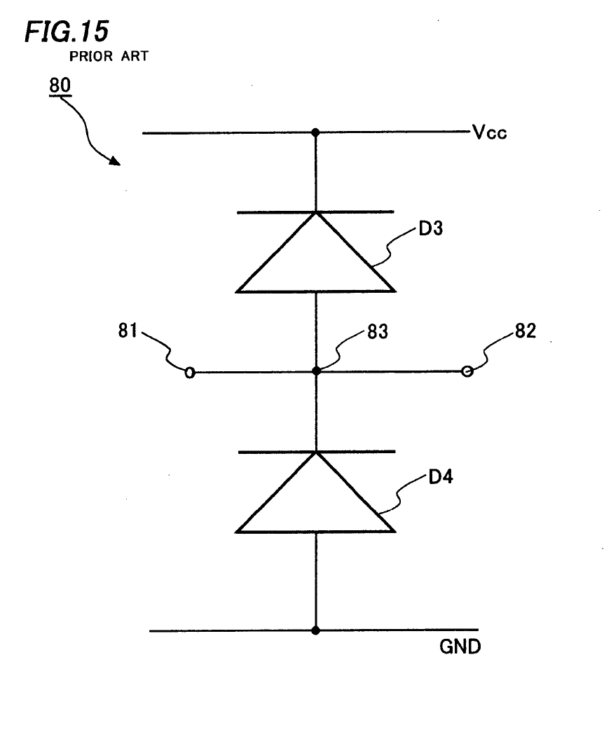

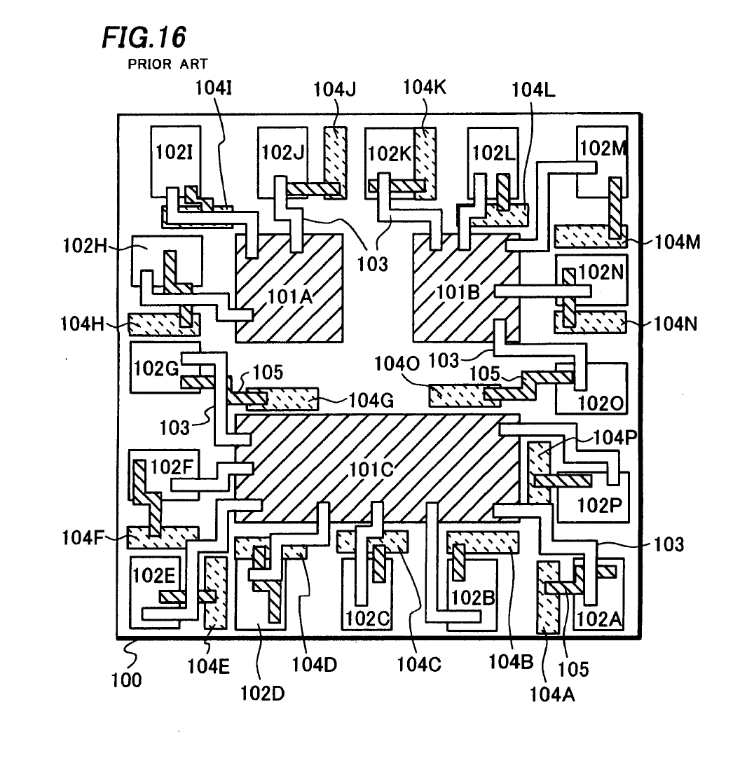

Each of cells 3 is formed around each of the circuit blocks 2A, 2B and 2C in the semiconductor device 1A and is connected to one of the circuit blocks 2A, 2B and 2C through an interconnection made of aluminum, aluminum alloy or copper. Each of the cells 3 has a pad and a protection circuit which is adjacent the pad and protects an internal circuit from electrostatic discharge damage. The protection circuit includes two diodes connected in series between Vcc and GND, for example, as shown in FIG. 15. A plurality of the cells 3 is disposed along a periphery of the semiconductor device 1A in this embodiment. However, there is no restriction on the positioning or the number of the cells 3.

A bottom layer metal (hereafter referred to as a first layer metal) 4a is a metal wiring formed on a silicon dioxide film 12b, for example, on the semiconductor substrate 12a of the semiconductor device 1A. The first layer metal 4a is connected to GND through the pad. This GND may be connected to the substrate (hereafter referred to as a substrate GND). The first layer metal 4a forms a wiring layer composed of aluminum, aluminum alloy or copper, for example, and electrically connects the cells 3 and the circuit blocks 2A, 2B and 2C.

A top layer metal Sa is a metal wiring formed in the top layer of the semiconductor device 1A which has a stacked structure excluding the first layer metal 4a. The top layer metal 5a is formed to surround the periphery of the semiconductor device 1A along the cells 3. The reference numeral 7 denotes an interlayer insulation film.

The BOX, as indicated in the figures, is formed on the circuit block 2A as a shielding body to cover the whole circuit block 2A in this embodiment. For example, when the circuit block 2A is a circuit processing high frequency signal and generates noise, this structure suppresses influence of the noise on the other circuit blocks 2B and 2C placed around the circuit block 2A.

The noise generated in the circuit block 2A does not go out of the BOX (does not invade the other circuit blocks 2B of 2C) and is led out of the semiconductor device 1A from a pad in a desired cell 3 through the metal portion of the BOX and the first layer metal 4a connected to the circuit block 2A.

When noise occurs in the circuit block 2B or 2C on the contrary, the BOX has a function to protect the circuit block 2A from the noise. In this case, the noise is led out of the semiconductor device 1A from a pad in desired cell 3 through the metal portion of the BOX and through the first layer metal 4a.

Here, the BOX may be formed either in the process to form the semiconductor device 1A which has a stacked structure, or the BOX may be formed in a separate process (that is, providing the BOX made of metal only such as aluminum, aluminum alloy and copper) and then placed on the circuit block 2A.

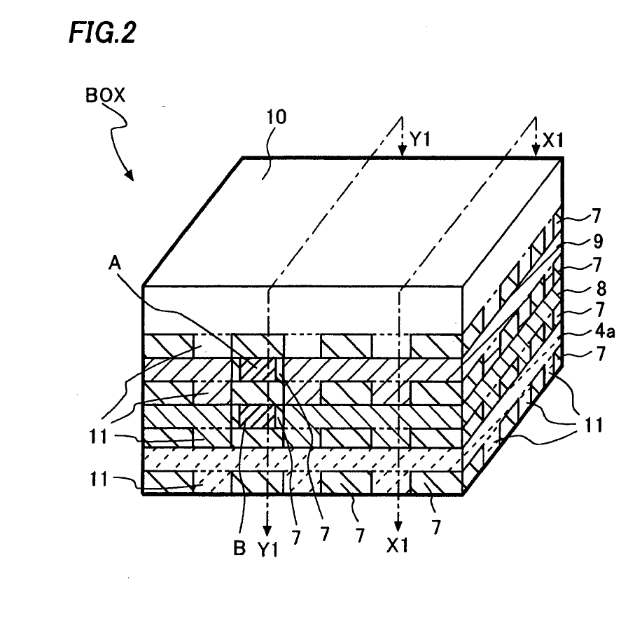

Explanation will be given referring to FIG. 2, which shows the BOX formed in the process to form the semiconductor device 1A having the stacked structure.

FIG. 2 is an oblique perspective figure of the BOX formed using the stacked structure of the semiconductor device 1A. This BOX has four layers of metal wirings. However there is no restriction on the number of layers.

The side surface of the BOX has the first layer metal 4a, a second layer metal 8, a third layer metal 9 and a fourth layer metal 10 with interlayer insulation films 7 between them. A top surface (lid) of the BOX is made of the fourth layer metal 10, and covers entire surface of the circuit block 2A.

The first layer metal 4a, the second layer metal 8, the third layer metal 9 and the fourth layer metal 10 are electrically connected with each other via through-holes 11. The through holes 11 are provided in the interlayer insulation films between the metal layers, and are filled with the metal of the metal layers. A part of the first layer metal 4a, the second layer metal 8, the third layer metal 9 or the fourth layer metal 10 may be buried in the through-holes 11. Or, refractory metal such as tungsten may be buried in the through-holes and the wirings may be formed on it.

There is no restriction on number or width of the through-holes 11. As the number of the through-holes increases, the area of the interlayer insulation film 7 on the side surface of the BOX decreases to make the semiconductor device more effective against the noise. Similarly as the width (diameter) of the through-hole 11 increases, the area of the interlayer insulation film 7 on the side surface of the BOX decreases to make the semiconductor device more effective against noise. This is because the noise is transmitted from inside to outside or from outside to inside of the BOX through portions of the interlayer insulation films 7 which are not shielded with the metal.

However, this embodiment includes a case in which the through-hole 11 is not formed on the side surface of the BOX, since in some cases the through-hole 11 can not be formed on the side surface because of various design restrictions. In this case, all the side surface of the BOX is made of the interlayer insulation film 7, making the semiconductor device insufficient against the noise. Even so, a certain degree of effect as the counter measure against noise can be expected, since the fourth layer metal 10 forms the top surface of the BOX to cover the top surface of the circuit block 2A and suppresses incoming noise from above the BOX and outgoing noise from the top of the BOX.

A window A and a window B are provided in a side wall of the BOX to exchange signals between the circuit block 2A in the BOX and the outside, making an exit and an entrance of the signals.

An example in which the window A is formed on the same plane as the third layer metal 9 is shown in FIG. 2. A wiring A, which will be described later, is formed in the window A, and a thin layer of interlayer insulation film 7 is formed around the window A so that the wiring A and the third layer metal 9 are not electrically connected. A thin layer of interlayer insulation film 7 is also formed around the window B.

In the example shown in FIG. 2, the window A and the window B are formed in the same position horizontally (the window A is located above the window B). However, there is no restriction on location or number of the windows in this embodiment, and the location is not limited to the position shown in FIG. 2.

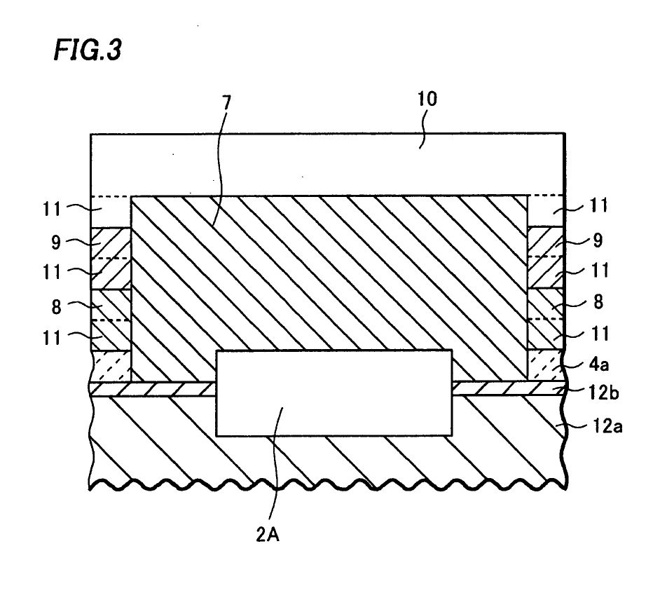

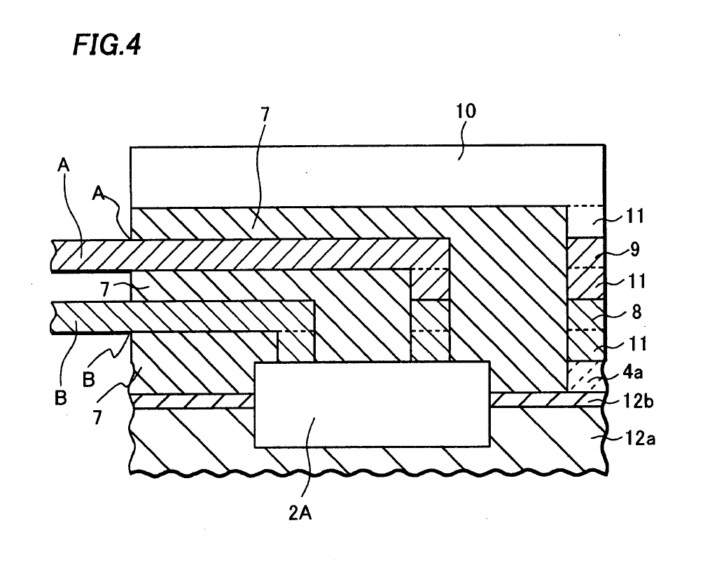

Next, the inside of the BOX shown in FIG. 2 will be explained referring to FIG. 3 and FIG. 4. FIG. 3 is a cross-sectional view showing section X1-X1 in FIG. 2. FIG. 4 is a cross-sectional view showing section Y1-Y1 in FIG. 2.

The BOX is formed on the circuit block 2A formed on the semiconductor substrate 12a. In the BOX, the fourth layer metal 10 makes the lid of the BOX as the top layer metal. There are the interlayer insulation films 7 between the circuit block 2A and the fourth layer metal 10 in the BOX. The side surface of the BOX is composed of the first layer metal 4a, the second layer metal 9, the third layer metal 9, the fourth layer metal 10 and the interlayer insulation films 7 with the through-holes 11 filled with the metal.

More detailed explanation regarding FIG. 3 will be given hereafter. FIG. 3 shows the through-holes 11 on the side surface of the BOX but does not include the window A or the window B. The interlayer insulation films 7 are formed in the BOX. The four layers of metal (the first layer metal 4a, the second layer metal 8, the third layer metal 9 and the fourth layer metal 10) and the interlayer insulation films 7 with the through-holes 11 filled with the metal of the first layer metal 4a, the second layer metal 8, the third layer metal 9 and the fourth layer metal 10 (aluminum, aluminum alloy or copper, for example) are formed on the side surface of the BOX. The fourth layer metal 10, which makes the lid of the BOX, is connected to the third layer metal 9, the second layer metal 8 and the first layer metal 4a connected with the substrate GND via the through-holes 11. Thus electric potentials of all metal layers are at GND potential.

Due to the structure described above, the adverse effect of the noise generated in the BOX on the other circuit blocks around the BOX can be suppressed by leading the noise to the first layer metal 4a connected to the substrate GND through each layer of the metal on the side surface and the lid (the top layer metal) of the BOX. Similarly, the circuit in the BOX is protected against the noise from the outside.

FIG. 4 is the cross-sectional view of the section Y1-Y1 in FIG. 2, which includes the window A and the window B. A wiring A is led into the BOX through the window A and is bent in the BOX so that it is connected to a desired position on the circuit block 2A formed on the semiconductor substrate 12a. Similarly, a wiring B is led into the BOX through the window B and is connected to a desired position on the circuit block 2A. The wiring A and the wiring B represent wirings for incoming signals and outgoing signals of the circuit block 2A. There is no restrictions on the number, position or shape of the wirings.

When the BOX is formed in the process to form the semiconductor device 1A, the wiring A is formed together with the third layer metal 9 and the wiring B is formed together with the second layer metal 8 in this embodiment.

Although the fourth layer metal 10 is shown thicker than the first layer metal 4a, the second layer metal 8 or the third layer metal 9 in FIG. 3 and in FIG. 4, thickness of each layer of metal can be the same or different from each other. They vary depending on various structures or requirements due to the design of the semiconductor device 1A.

In the first embodiment of this invention, as described above, the adverse effect of the noise is suppressed by forming the BOX to enclose the circuit block 2A which would otherwise adversely affect the other circuit blocks 2B and 2C. Also, when the circuit block 2B or 2C has adverse effects, the effects are suppressed by protecting the circuit block 2A with the BOX. The BOX may be formed to enclose each of the circuit blocks 2B and 2C, or to enclose each of the circuit blocks 2A, 2B and 2C.

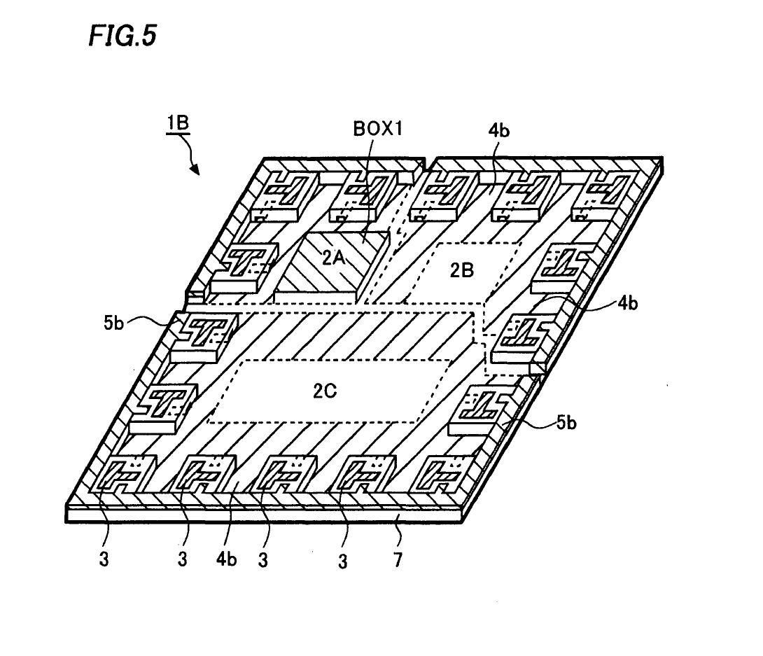

Next, the second embodiment (semiconductor device 1B) of this invention will be explained referring to FIG. 5. The second embodiment shown in FIG. 5 differs from the first embodiment shown in FIG. 1 in that the first layer metal 4b is formed over entire surface of the silicon dioxide film except for the circuit blocks 2A, 2B and 2C on the semiconductor device 12a.

Because of it, impedance in the semiconductor device 1B is reduced in the second embodiment of this invention, since the first layer metal 4b connected to the substrate GND has larger area than that of the first embodiment.

In the second embodiment of this invention, the semiconductor device 1B realizes reduced impedance in addition to the effect of the first embodiment described above.

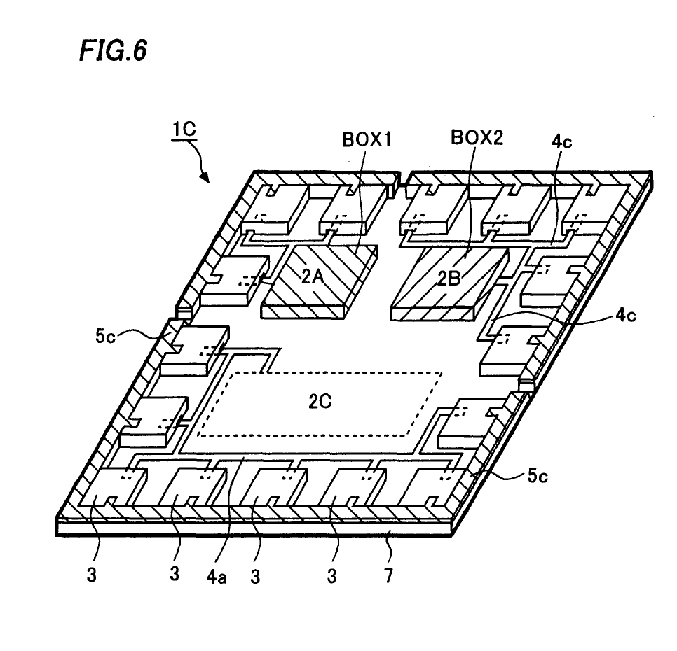

Next, the third embodiment of this invention will be explained referring to FIG. 6 through FIG. 12. FIG. 6 is the oblique perspective figure showing the semiconductor device 1C according to the third embodiment of this invention.

The semiconductor device 1C differs from the first embodiment of this invention in that it has two BOXes. Also a planar metal 13 is formed in the BOX. Heights of BOX1 and BOX2 are not necessary equal.

The first feature of this embodiment will be described hereafter. The BOX1 and the BOX2, which are different in height from each other, are formed so that each encloses each of the circuit blocks 2A and 2B, respectively. The BOX1 and the BOX2 have function of protecting against the influence of the noise as described above.

Here, the BOX1 and the BOX2 may be formed either in the process to form the semiconductor device 1C which has a stacked structure, or the BOX1 and the BOX2 may be formed in a separate process (providing the BOX1 and the BOX2 made of only a metal such as aluminum, aluminum alloy and copper) and then placed on the circuit blocks 2A and 2B.

The BOX1 and the BOX2 are different in height in this embodiment. In the example, the BOX1 has a four-layer structure, while the BOX2 has a three-layer structure.

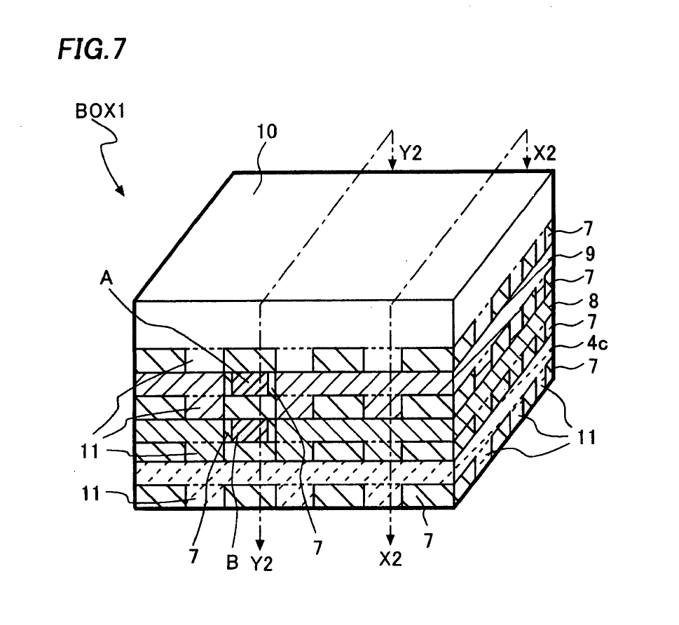

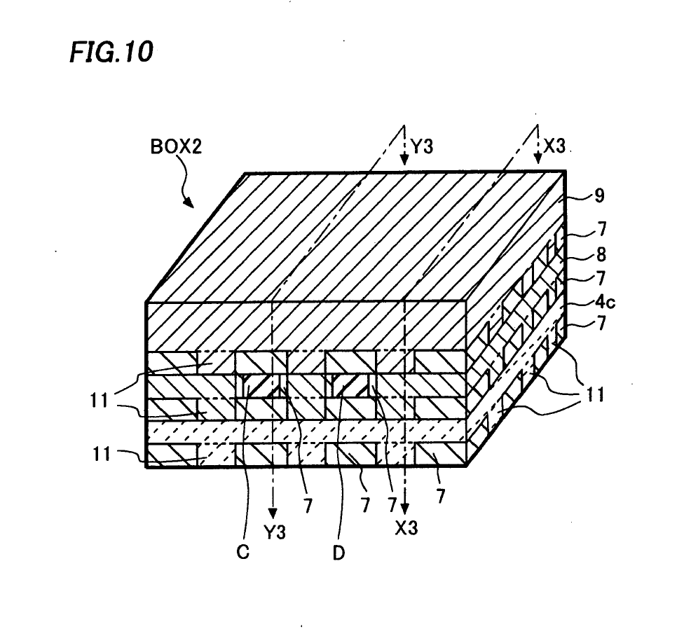

Explanation will be given on the structure of the BOX1 referring to FIG. 7 through FIG. 9, and on the structure of the BOX2 referring to FIG. 10 through FIG. 12, both of which are formed in the process to form the semiconductor device 1C which has the stacked structure.

FIG. 7 is an oblique perspective figure showing the BOX1 in this embodiment. Since there is no difference in the oblique perspective figure of the BOX1 in FIG. 7 from the BOX in FIG. 2, explanation on the figure is omitted.

The second feature of this embodiment is that a layer of metal (a planar metal 13, which will be described later) is formed widely in each of the BOX1 and the BOX2 on the same plane as one of the intermediate layer metal. Here, “widely” means that the area of the planar metal 13 is larger than the area of the interlayer insulation film 7 formed on the same plane.

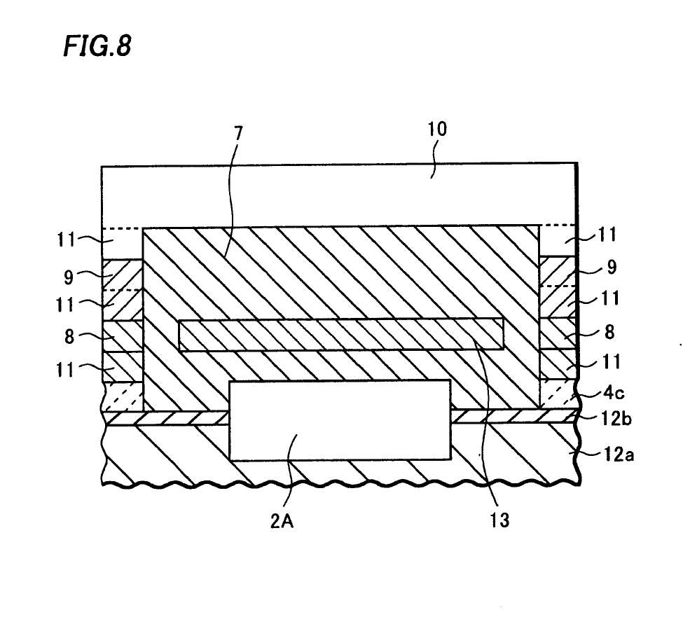

Next, structures of the BOX1 and the BOX2 will be described referring to FIG. 8 through FIG. 11. The BOX1 is formed to enclose the circuit block 2A formed on the semiconductor substrate 12a. The fourth layer metal 10 makes a lid (a top layer metal) of the BOX1, and the interlayer insulation films 7 are formed in the BOX1. The side surface of the BOX1 includes a first layer metal 4c, the second layer metal 8, the third layer metal 9, the fourth layer metal 10 and the interlayer insulation films 7 with the through-holes 11 filled with the metal as described above.

FIG. 8 is the cross-sectional view of the section X1-X1 in FIG. 7, which includes the through-holes 11 on the side surface of the BOX 1, but does not include the window A or the window B.

In the BOX 1, the second layer metal 8 makes a plane (hereafter referred to as the planar metal 13) almost as wide as the fourth layer metal 10. The planar metal 13 is formed parallel to the fourth layer metal 10. Although the planar metal 13 is formed on the same plane as the second layer metal 8 formed on the side surface of the BOX 1, they are separated by the interlayer insulation film 7 and are not electrically connected.

In FIG. 8, the second layer metal 8 is in plane with the planar metal 13. However, any metal layer other than the top layer metal (the fourth layer metal 10 in FIG. 8) and the first layer metal 4c may be in plane with the planar metal 13, depending on restrictions in the design and other conditions. That is, when the structure has eight layers of metal, for example, one of the metal layers between the second layer metal and the seventh layer metal may be in plane with the planar metal 13. Or a plurality of planar metals 13, for example the second layer metal and the fifth layer metal, may be formed. The interlayer insulation films 7 are formed both on and under the planar metal 13 in the BOX1.

The four metal layers (the first layer metal 4c, the second layer metal 8, the third layer metal 9 and the fourth layer metal 10) and the interlayer insulation films 7 with the through-holes 11 filled with the metal of the first layer metal 4c, the second layer metal 8, the third layer metal 9 and the fourth layer metal 10 (aluminum, aluminum alloy or copper, for example) are formed on the side surface of the BOX1. The fourth layer metal 10, which makes the lid of the BOX1, is connected to the third layer metal 9, the second layer metal 8 and the first layer metal 4c connected with the substrate GND via the through-holes 11.

The noise generated in the BOX1 (the circuit block 2A) is led out of the semiconductor device 1C from a pad in a desired cell 3 via each layer of metal and through the first layer metal 4c connected to the substrate GND. Or, the noise may be led out of the BOX1 through the planar metal 13 in the BOX1. The planar metal 13 is connected to GND in this case. Also the planar metal 13 may be further connected to the substrate GND. The noise is, thus, intercepted not to adversely affect the other circuit blocks around the BOX 1.

When the circuit in the BOX1 is to be protected from the noise which occurs in another circuit block 2C, it is led out of the semiconductor device 1C through the metal layers of the BOX1 and eventually through the first layer metal 4c, even though the noise reaches the BOX1. The circuit block 2A is not affected by the noise and can make a stable operation.

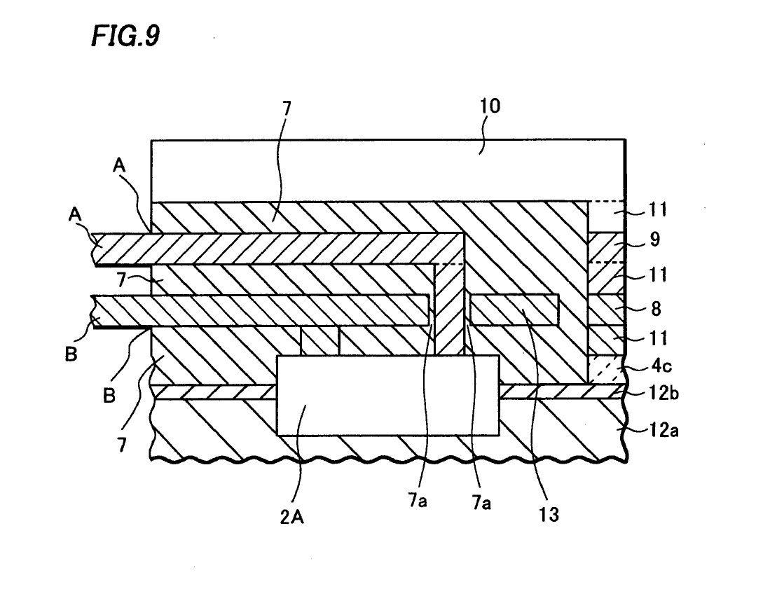

FIG. 9 is the cross-sectional view of the section Y2-Y2 in FIG. 7, which includes regions forming the window A and the window B.

A wiring A is led into the BOX1 through the window A and is bent in the BOX1 so that it is connected to a desired position on the circuit block 2A formed on the semiconductor substrate 12a. Similarly, a wiring B is led into the BOX1 through the window B and is connected to a desired position on the circuit block 2A. The wiring A and the wiring B represent wirings for incoming signals and outgoing signals of the circuit block 2A. There is no restriction on the number, position or shape of the wirings.

A part of the second layer metal 8 makes the planar metal 13, as shown in FIG. 8. That is, the wiring B and the planar metal 13 are made of the same layer of metal. The planar metal 13 and the wiring A are separated by the interlayer insulation film 7a of a certain thickness in order to prevent short circuit.

Next, the BOX2 will be explained referring to FIG. 10. The BOX2 has lower stacked structure compared with the BOX1. Three-layer structure is shown in FIG. 10. Difference from the BOX1 is in that the top layer metal is the third layer metal 9.

The BOX2 is formed on the circuit block 2B formed on the semiconductor substrate 12a and has a window C and a window D. The windows C and D are formed on the same plane as the second layer metal 8. A wiring C is provided in the window C while a wiring D is provided in the window D. The wiring C and the wiring D are to exchange signals between the circuit blocks, similar to the wiring A and the wiring B of the BOX1.

The third layer metal 9 makes a lid (a top layer metal) of the BOX2, and the interlayer insulation films 7 are formed in the BOX2. The side surface of the BOX2 includes a first layer metal 4c, the second layer metal 8, the third layer metal 9 and the interlayer insulation films 7 with the through-holes 11 filled with the metal as described above.

That is, in the BOX2, the third layer metal 9, which makes the top layer metal, and the semiconductor substrate 12a are electrically connected through the side surface of the BOX2. Therefore the third layer metal 9 and the substrate GND are kept at the same electric potential.

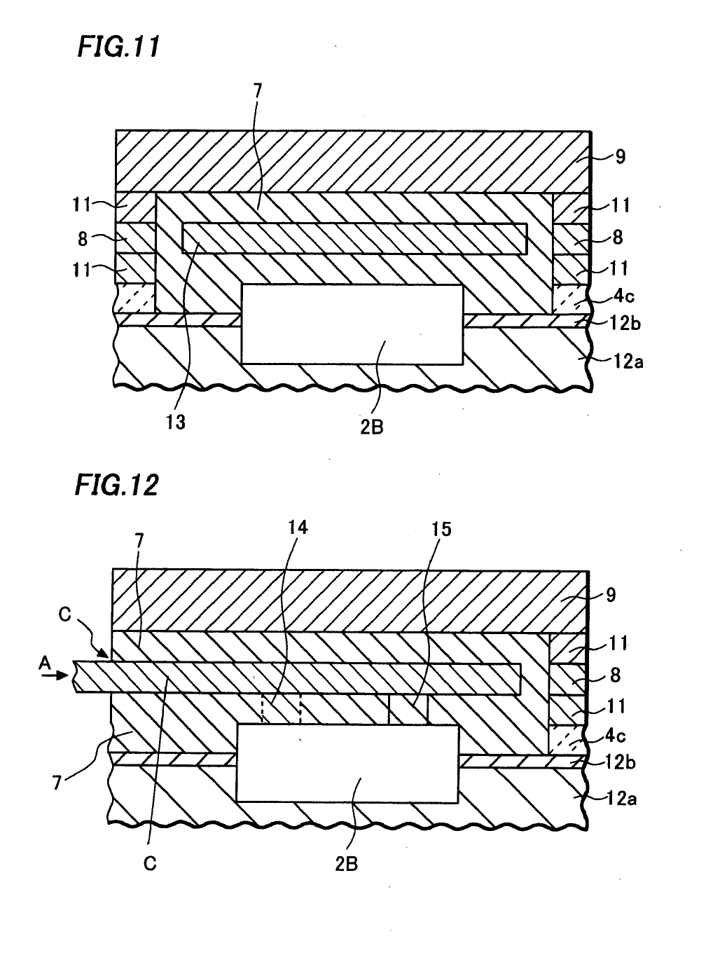

Next, the inside of the BOX2 shown in FIG. 10 will be explained referring to FIG. 11 and FIG. 12. FIG. 11 is the cross-sectional view of the section X3-X3 of the BOX2 in FIG. 10, which does not include the window C or the window D.

The second layer metal 8 is in plane with the planar metal 13, and the planar metal 13 is electrically separated from the second layer metal 8 with the interlayer insulation film 7, as the planar metal 13 in the BOX1 is.

The side surface of the BOX2 includes the first layer metal 4c, the second layer metal 8, the third layer metal 9 and the interlayer insulation films 7 with the through-holes 11 filled with the metal as described above. The third layer metal 9 which makes the lid of the BOX2 is connected to the first layer metal 4c connected to the substrate GND, through which the noise is led out of the semiconductor device 1C. Or, the noise may be led out of the semiconductor device 1C through the planar metal 13 connected to the GND.

FIG. 12 is the cross-sectional view of the section Y3-Y3 in FIG. 10, which includes the window C.

The wiring C is led into the BOX2 through the window C and is bent in the BOX2 so that it is connected to a desired position on the circuit block 2B formed on the semiconductor substrate 12a. The wiring C is one of wirings for the incoming signals and the outgoing signals of the circuit block 2B. The wiring D is other of the wiring. There is no restriction on the number, position or shape of the wirings.

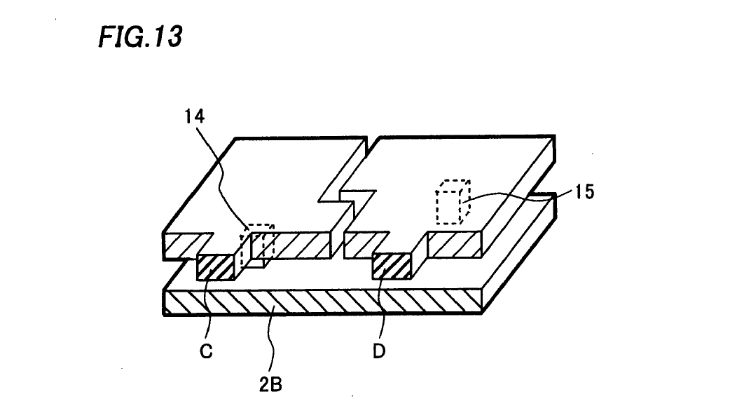

The wiring C and the wiring D are formed on the same plane as the second layer metal 8 and are electrically connected with the circuit block 2B through the through-holes 14 and 15. FIG. 13 is a figure viewed from an angle indicated with an arrow A in FIG. 12. Note that FIG. 13 is the figure to show the wirings C and D and does not show the interlayer insulation films 7 or the third layer metal 10.

In the embodiment of this invention, as described above, the adverse effect of the noise from the circuit blocks 2A and 2B is suppressed by forming the BOX1 and the BOX2 to enclose the circuit blocks 2A and 2B which would otherwise adversely affect the other circuit block 2C. Also, when the circuit block 2C has the adverse effect, the effect of the noise from the circuit block 2C is suppressed by protecting the circuit blocks 2A and 2B with the BOX1 and the BOX2.

The circuit GND of the circuit block and the substrate GND can be provided separately to stabilize operation of the circuit block by using a metal layer other than the first layer metal or the top layer metal as the planar metal.

Also, heat dispersion characteristics are improved because the metal is used for the lid (top layer metal) and for the side surface in the BOXes.

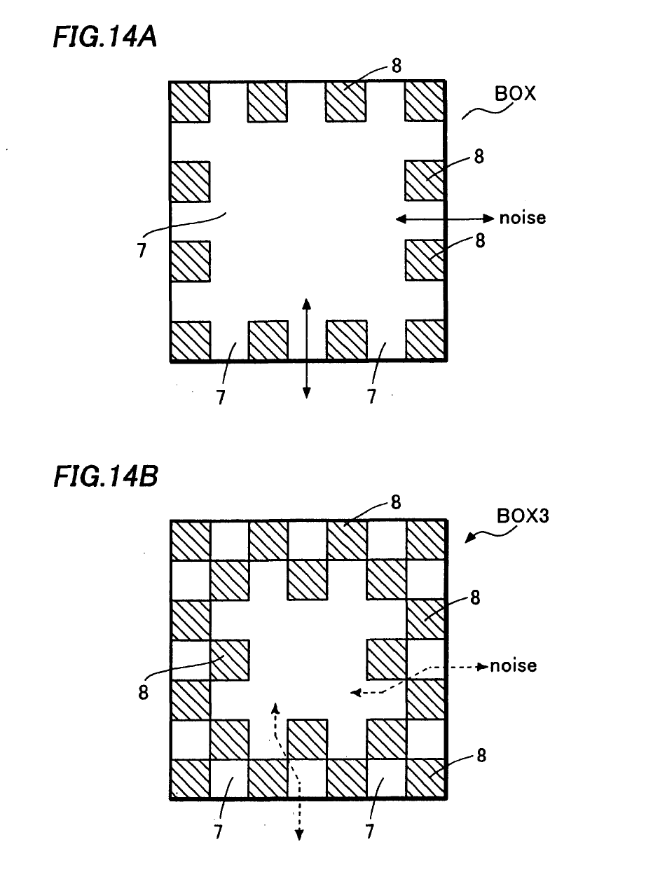

The BOXes have the first layer metal, the second layer metal, the third layer metal, the fourth layer metal and the interlayer insulation films with through-holes filled with metal in the embodiment described above. In this case, as described above, the shield against the noise is weakened in portions where the interlayer insulation films are present (See FIG. 14A.). In the fourth embodiment of this invention, a layer of metal is formed in two rows in a staggered configuration as shown in FIG. 14B. That is to say, a fence of double rows of metal layer is formed around the periphery of BOX3. More metal layer are formed in the region through which the noise comes in and goes out, leading to improved effectiveness of shielding the noise. Three rows of the metal layer may be formed to further improve the effectiveness of shielding.

There is a plurality of BOXes in some of the embodiments of this invention. There is no restriction on the number or disposition of the BOXes. The BOXes may be placed adjacent to each other or separated from each other with large clearance.

In addition, each of the embodiments of this invention may include a semiconductor device which incorporate an active element such as a bipolar or MOS element, a semiconductor device having a Gilbert cell structure and requiring symmetry such as a mixer or an AGC circuit, a semiconductor device used in a high frequency region, a semiconductor device using SiGe process and semiconductor devices for a satellite TV, a terrestrial TV and an RF LAN.

In the semiconductor device having a plurality of the circuit blocks, by enclosing a certain circuit block with the BOX, the noise from the circuit block is kept from affecting the other circuit blocks.

Impedance of the semiconductor device is reduced by forming the bottom layer metal widely over the surface of the semiconductor substrate except for the circuit blocks.

Furthermore, the circuit GND of the circuit blocks and the substrate GND may be provided separately to stabilize operation of the circuit block by forming the planar metal connected to the GND in the BOX. Also improved heat dispersion characteristics are obtained because the BOX includes metal elements.

What is claimed is:

1. A semiconductor device comprising:
a circuit block formed on a semiconductor substrate; and
a shield comprising a lower metal layer, an upper metal layer and an interlayer insulation film disposed between the lower metal layer and the upper metal layer, the shield covering the circuit block.

2. The semiconductor device of claim 1, wherein the circuit block comprises a circuit which includes at least a resistor, a transistor or a capacitor.

3. The semiconductor device of claim 1, further comprising a wiring line connected to the circuit block, wherein the wiring line extends outside of the shield through a window formed in a side wall of the shield.

4. The semiconductor device of claim 1, wherein at least the lower metal layer or the upper metal layer is configured to a part of a metal layer that is formed to be a part of the semiconductor device other than the shield.

5. The semiconductor device of claim 1, further comprising another shield of a different height.

6. The semiconductor device of claim 1, wherein the shield comprises an outside wall and an inside wall disposed inside the outside wall, wherein a metal portion of the inside wall is disposed to cover an insulation portion of the outside wall.

7. A semiconductor device comprising:
a circuit block formed on a semiconductor substrate; and
a shield comprising a lower metal layer, an upper metal layer and an interlayer insulation film disposed between the lower metal layer and the upper metal layer, the shield covering the circuit block; and
an intermediate metal layer disposed inside the shield.

8. The semiconductor device of claim 7, wherein the plane of the intermediate metal layer also includes within the shield the interlayer insulation film, and the surface area of the intermediate metal layer is larger than the surface area of the insulation film of said plane within the shield.

9. The semiconductor device of claim 7, wherein the shield comprises an outside wall and an inside wall disposed inside the outside wall, wherein a metal portion of the inside wall is disposed to cover an insulation portion of the outside wall.

10. A semiconductor device comprising:
a first circuit block formed on a semiconductor substrate;
a second circuit block formed on the semiconductor substrate; and
a shield comprising a top portion made of a metal and covering only the first circuit block, the top portion being configured to be at a ground potential.

11. The semiconductor device of claim 10, wherein the entire shield is made of the metal.

12. The semiconductor device of claim 10, wherein the shield comprises a side wall that includes a part of the top portion, a metal portion and an insulation portion disposed at least between the part of the top portion and the metal portion.

13. The semiconductor device of claim 12, wherein the top portion and the metal portion is electrically connected.

14. The semiconductor device of claim 10, further comprising an insulation body filling in the inside of the shield.

15. The semiconductor device of claim 12, wherein the side wall comprises an outside wall and an inside wall disposed inside the outside wall, wherein the metal portion of the inside wall is disposed to cover the insulation portion of the outside wall.
